(19) United States
(12) Patent Application Publication
(10) Pub. No.: US 2026/0092370 A1
(43) Pub. Date: Apr. 2, 2026

(54) CHEMICAL PROCESS ENHANCEMENT THROUGH MODULATION OF GAS OR PRESSURE CONTROL

(71) Applicant: Applied Materials, Inc., Santa Clara, CA (US)

(72) Inventors: Sameh HELMY, Santa Clara, CA (US); Edy CARDONA, Fremont, CA (US); Christopher S. OLSEN, Fremont, CA (US)

(21) Appl. No.: 19/067,312

(22) Filed: Feb. 28, 2025

Related U.S. Application Data
(60) Provisional application No. 63/701,949, filed on Oct. 1, 2024.

(51) Int. Cl. C23C 16/455; C23C 16/44

(52) U.S. Cl. CPC C23C 16/45557; C23C 16/4412; C23C 16/45519; C23C 16/45565

(57) ABSTRACT

The present disclosure generally relates to modulating pressure within an inner chamber of a processing chamber and/or modulating velocity of a processing gas. The processing chamber comprises a chamber, a gas inlet configured to flow processing gas into the chamber, an exhaust configured to remove processing gas from the chamber, a substrate holder disposed between the gas inlet and the exhaust, and a first injector configured to pulse inert or process gas into the chamber. In one embodiment, the processing chamber further comprises a second injector configured to pulse the inert gas into the chamber, where the first injector pulses inert gas before the substrate holder and the second injector pulses inert gas after the substrate holder. In another embodiment, the processing chamber comprises a pressure control valve configured to close or partially close being processing of a substrate to constrict the exhaust.

### CROSS-REFERENCE TO RELATED APPLICATIONS

This application claims benefit of U.S. provisional patent application Ser. No. 63/701,949, filed Oct. 1, 2024, which is herein incorporated by reference.

### BACKGROUND

### Field

Aspects of the present disclosure generally relate to modulating pressure within a reactor and/or modulating velocity of a processing gas in methods and systems for processing substrates.

### Description of the Related Art

During substrate processing operations, process gases can flow over substrates. The velocity of the processing gas and the pressure within the processing chamber both have an impact on how the substrate is processed, as the velocity and pressure can modulate the chemical reaction of the substrate. However, the velocity of the gas and the chamber pressure can also effect one another. For optimal wafer processing, the gas injects and pump valves must be well positioned, pulse capable and synchronized.

Therefore, there is a need for improved apparatus, systems, and methods to modulate and increase the velocity of the processing gas and the pressure within the chamber.

### SUMMARY

The present disclosure generally relates to modulating pressure within an inner chamber of a processing chamber and/or modulating velocity of a processing gas. Gas or pressure pulsing can be implemented continuously throughout the entire duration of the process, as opposed to a single pulse as implemented in previous art. Furthermore, the use of separate pulse injectors in addition to the primary process injector allows for the kinetic chemical reaction rate to be modulated or kept constant throughout the process, independent of pulsing. The processing chamber comprises a chamber, a gas inlet configured to flow processing gas into the chamber, an exhaust configured to remove processing gas from the chamber, a substrate holder disposed between the gas inlet and the exhaust, and a first injector configured to pulse inert or process gas into the chamber. In one embodiment, the processing chamber further comprises a second injector configured to pulse the inert gas into the chamber, where the first injector pulses inert gas before the substrate holder and the second injector pulses inert gas after the substrate holder. In another embodiment, the processing chamber comprises a pressure control valve configured to close or partially close being processing of a substrate to constrict the exhaust.

In one embodiment, a processing chamber comprises an inner chamber, a gas inlet disposed on a first end of the inner chamber, the gas inlet being configured to flow processing gas into the inner chamber, an exhaust disposed on a second end of the inner chamber opposite the first end, the exhaust being coupled to a pump configured to remove processing gas from the inner chamber, a substrate holder disposed between the gas inlet and the exhaust, the substrate holder being configured to hold one or more substrates, a first gas injector disposed between the gas inlet and the substrate holder, the first gas injector being configured to pulse an inert or processing gas into the inner chamber a first time, a second gas injector disposed between the substrate holder and the exhaust, the second gas injector being configured to pulse the inert or processing gas into the inner chamber a second time, and a controller coupled to the first and second gas injectors, the controller being configured to control the first and second gas injectors such that the timing of the pulses of the inert or processing gas the first and second times are synchronized.

In another embodiment, a processing chamber comprises an inner chamber, a gas inlet disposed on a first end of the inner chamber, the gas inlet being configured to flow processing gas into the inner chamber, an exhaust disposed on a second end of the inner chamber opposite the first end, the exhaust being coupled to a pump configured to remove processing gas from the inner chamber, a substrate holder disposed between the gas inlet and the exhaust, the substrate holder being configured to hold one or more substrates, a pressure control valve (PCV) coupled to the exhaust, the PCV configured to close or partially close being processing of a substrate to constrict the exhaust, and a gas injector configured to pulse inert or process gas into the inner chamber.

In another embodiment, a processing system comprises a processing chamber, the processing chamber comprising an inner chamber, a gas inlet disposed on a first end of the inner chamber, the gas inlet being configured to flow processing gas into the inner chamber, an exhaust disposed on a second end of the inner chamber opposite the first end, the exhaust being coupled to a pump configured to remove processing gas from the inner chamber, a substrate holder disposed between the gas inlet and the exhaust, the substrate holder being configured to hold one or more substrates, a first gas injector disposed between the gas inlet and the substrate holder, the first gas injector being configured to pulse an inert or processing gas into the inner chamber a first time, a second gas injector disposed between the substrate holder and the exhaust, the second gas injector being configured to pulse the inert or processing gas into the inner chamber a second time, and a controller coupled to the first and second gas injectors, the controller being configured to control the first and second gas injectors such that the timing of the pulses of the inert or processing gas the first and second times are synchronized.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1A is a schematic partial sectional view of a system for processing substrates, according to one implementation.

FIG. 1B is an enlarged partial schematic view of the system shown in FIG. 1A during the processing operation, according to one implementation.

FIG. 1C is a schematic graphical illustration of an oscillation frequency, according to one implementation.

FIG. 2A is a schematic partial top view of the system shown in FIG. 1A, according to one implementation.

FIG. 2B is a schematic partial top view of the system shown in FIG. 1A, according to one implementation.

FIG. 3A schematically illustrates a portion of a processing chamber, according to one embodiment.

FIG. 3B schematically illustrates a portion of a processing chamber, according to another embodiment.

FIG. 3C illustrates a first graph showing gas flows versus time during processing a substrate in the processing chamber of FIG. 3A, and a second graph showing gas velocity versus time during processing a substrate in the processing chamber of FIG. 3A, according to embodiments.

FIG. 4A schematically illustrates a portion of a processing chamber, according to another embodiment.

FIG. 4B illustrates a first graph showing gas flows versus time during processing a substrate in the processing chamber of FIG. 4A, and a second graph showing pressure of the inner chamber versus time during processing a substrate in the processing chamber of FIG. 4A, according to embodiments.

FIG. 5A illustrates a showerhead configuration of the chamber of FIG. 3A, according to one embodiment.

FIG. 5B illustrates a showerhead configuration of the chamber of FIG. 4A, according to one embodiment.

FIG. 6A illustrates a cross-sectional view of a furnace configuration of the chamber of FIG. 3A, according to another embodiment.

FIG. 6B illustrates a cross-sectional view of a furnace configuration of the chamber of FIG. 4A, according to another embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relates to modulating pressure within an inner chamber of a processing chamber and/or modulating velocity of a processing gas. The processing chamber comprises a chamber, a gas inlet configured to flow processing gas into the chamber, an exhaust configured to remove processing gas from the chamber, a substrate holder disposed between the gas inlet and the exhaust, and a first injector configured to pulse inert or process gas into the chamber. In one embodiment, the processing chamber further comprises a second injector configured to pulse the inert gas into the chamber, where the first injector pulses inert gas before the substrate holder and the second injector pulses inert gas after the substrate holder. In another embodiment, the processing chamber comprises a pressure control valve configured to close or partially close being processing of a substrate to constrict the exhaust.

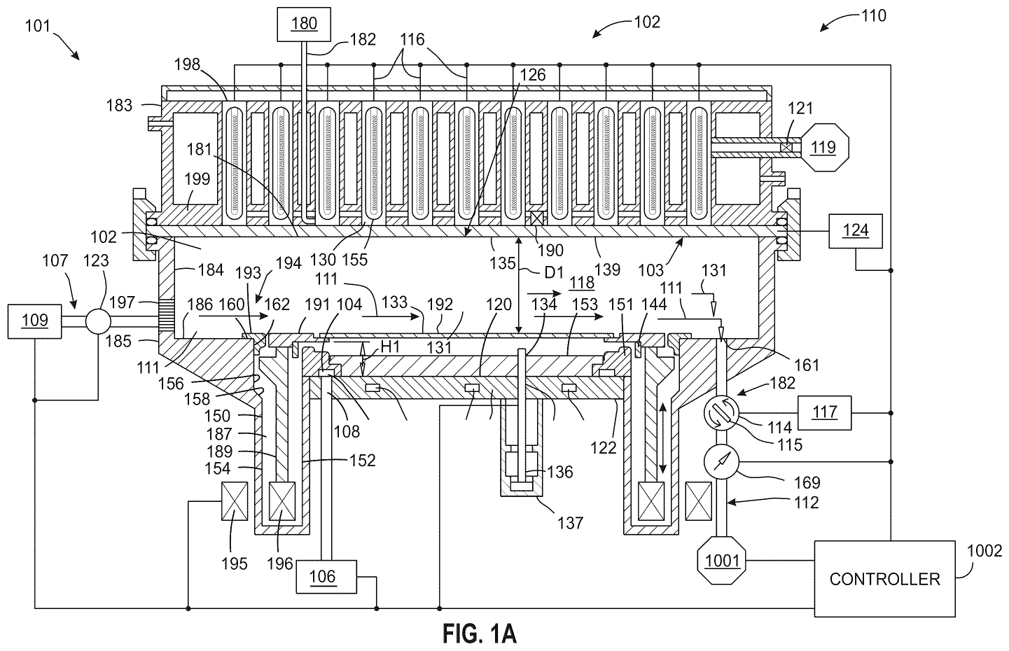

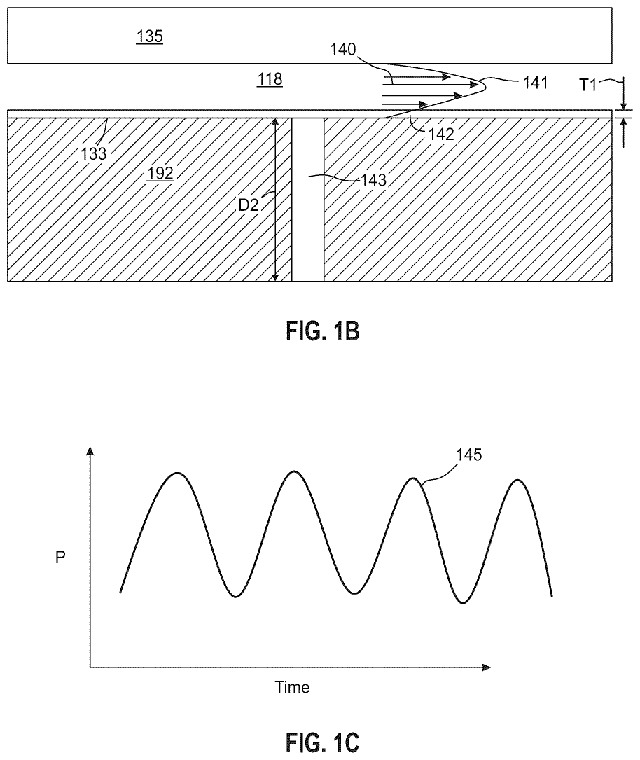

FIG. 1A is a schematic partial sectional view of a system 101 for processing substrates, according to one implementation. The system 101 includes a processing chamber 110. The processing chamber 110 includes a chamber body 185 having a first portion 184 forming a sidewall of the chamber body 185, a second portion 186 coupled to the first portion and partially defining a floor or base of the chamber body 185, a window 135 disposed on the first portion 184 of the chamber body 185, and a lamp assembly 183 disposed on the window 135. A chamber base 188 is coupled to the chamber body 185 opposite the window 135. The lamp assembly 183 includes a housing 199 with a plurality of openings 130 formed therein. A plurality of lamps 155 is disposed in the housing 199, and a single lamp 155 is disposed within a corresponding opening 130. The lamps 155 are disposed in respective electrical sockets 198 which are concentrically aligned with the corresponding openings 130. The lamps 155 are coupled to a controller 1002 via a plurality of electrical conduits 116 and the electrical sockets 198.

During operation, a substrate 192 is loaded into the processing chamber 110 through a transfer port, such as a slit valve port. The substrate 192 is positioned on a plurality of lift pins 136. The lift pins 136 actuate to position the substrate 192 onto a substrate support 191. The lamps 155 heat the substrate 192 to a desired processing temperature while the substrate support 191 is rotated to rotate the substrate about a central axis during a processing operation. During the processing operation, one or more process gases are flowed into the processing chamber 110 to deposit a new material layer or modify a previously deposited layer on the substrate 192. After completion of the processing operation, the substrate 192 may undergo one or more additional processing operations within the process chamber 110 or the substrate 192 may be removed from the processing chamber 110. After processing of the substrate 192 in the processing chamber 110, the plurality of lift pins 136 are actuated to raise the substrate 192 from the substrate support 191. The substrate 192 is then removed from the processing chamber 110 through the transfer port.

The processing operation conducted in the processing chamber 110 includes one or more of an oxidation operation, a plasma immersion ion implantation operation, an epitaxial deposition operation, a chemical vapor deposition (CVD) operation, an atomic layer deposition (ALD) operation, an etching operation, or a thermal annealing operation. The processing chamber 110 described is an oxidation chamber. The present disclosure contemplates that aspects of the system 101 and the processing chamber 110 may be used in conjunction with a plasma immersion ion implantation chamber, an epitaxial deposition chamber, a chemical vapor deposition (CVD) chamber, a physical vapor deposition (PVD) chamber, an atomic layer deposition (ALD) chamber, an etching chamber, or a thermal annealing chamber.

The lamps 155 emit electromagnetic (EM) radiation that passes through the window 135 and towards the substrate 192 disposed in the processing chamber 110 to heat the substrate 192 to a processing temperature. The window 135 is typically made of a material chemically resistant to the processing environment and able to allow one or more wavelengths of EM radiation emitted by the plurality of lamps 155 to pass through the window 135 without being substantially attenuated. For example, quartz may be used as the window 135 material. Other suitable materials include, but are not limited to, sapphire, ceramic, and glass.

The window 135 may be coated with an anti-reflective coating, or suitable filters, on one or both sides of the window 135. For example, optional ultra-violet (UV) filters can be used to avoid generation of ions and radicals in the chamber or damage to UV-sensitive structures on the substrate 192 if the lamps 155 have significant UV output. As another example, optional notch filters can be used to block narrow band radiation emitted from the lamps 155. In one embodiment, which can be combined with other embodiments, a filter 139 is disposed on an inside (e.g. process-facing) surface of the window 135. The filter 139 blocks radiation having wavelengths within a specific range from passing therethrough while allowing radiation having wavelengths outside of the specific range to pass. The filter 139 may be a plurality of alternating layers, such as oxide layers. In one embodiment, which can be combined with other embodiments, the filter 139 includes alternating silicon dioxide layers and titanium dioxide layers. For example, the filter 139 may include a total of 30 to 50 alternating layers, such as 35 to 45 alternating layers, with silicon dioxide layers located at opposite sides (e.g. an outside surface and an inside surface) of the filter 139. The filter 139 may be coated on an outside surface (e.g. facing the lamp assembly 183) of the window 135, an inside surface (e.g. facing the substrate support 191) of the window 135, or may be embedded within the window 135.

A reflector plate 153 is disposed on the chamber base 188 at a location within the processing chamber 110. The reflector plate 153 includes a plurality of openings 134 extending therethrough. The plurality of lift pins 136 are at least partially extendable within the processing chamber 110, and each of the lift pins 136 extends through one of the plurality of openings 134. The chamber base 188 a plurality of openings 138. Each of the plurality of openings 138 is aligned with a corresponding opening 134 of the plurality of openings 134 of the reflector plate 153. Each lift pin 136 is disposed within a receptacle 137 that is coupled to the chamber base 188 of the processing chamber 110 and concentric with the openings 134, 138. The lift pins 136 are magnetically actuated to raise and lower through the openings 134, 138.

During operation, the lamps 155 generate EM radiation that is emitted therefrom towards the substrate 192. A portion of the EM radiation typically passes through the substrate 192. The intensity of the EM radiation that passes through the substrate 192 is a function of the temperature of the substrate 192 and of the wavelength of the EM radiation. The system 101 can include radiation detectors (such as pyrometers and/or spectrometers) that measure blackbody radiation from the substrate and/or EM radiation emitted by the lamps 155 that has passed through the substrate 192 to measure a temperature of the substrate 192. An incident radiation detector 180 (such as a spectrometer or pyrometer) is optionally coupled to the housing 199 of the lamp assembly 183. The incident radiation detector 180 is used to sample the EM radiation emitted by the plurality of lamps 155 at a position before the emitted EM radiation interacts with the substrate 192. The EM radiation detected by the incident radiation detector 180 can be compared to the EM radiation detected by the radiation detectors to determine the amount of EM radiation that passes through the substrate 192 for substrate temperature measurements.

In one embodiment, which can be combined with other embodiments, the lamps 155 are arranged in the housing 199 in a honeycomb array. The lamps 155 may be divided into groups to define multiple heating zones on the substrate 192. In one embodiment, which can be combined with other embodiments, the heating zones are concentric rings. The radiation detectors may correspond to one of the zones. A temperature or temperature signal determined by operation of the radiation detectors, which may correspond to a defined heating zone, is provided to the controller 1002. The controller 1002 can individually adjust the power supplied the lamps 155 corresponding to the one or more heating zones to adjust the energy emitted thereto. The temperature profile across the substrate 192 can be adjusted as desired. Additionally, a plurality of detectors 190 can be disposed within the housing 199 (one detector 190 is shown in FIG. 1). The detector 190 is located between adjacent openings 130 and proximate to the window 135. The detector 190 is line-of-sight exposed to an upper surface 133 of the substrate 192 through the window 135. The detector 190 is used to determine a temperature of the substrate 192 at the upper surface 133 thereof. The detector 190 is an optical sensor, such as a pyrometer, and receives EM radiation emitted from the upper surface 133 of the substrate 192. A measured parameter of the EM radiation received by detector 190 from the substrate 192, such as wavelength or intensity, is used to determine a temperature of the substrate 192. In one embodiment, which can be combined with other embodiments, the detector 190 is a reflectometer that measures reflectivity of the substrate 192 for temperature measurements.

The processing chamber 110 includes an interior volume 102. A ceiling 103 of the interior volume 102 is defined at least partially by the window 135, such as the filter 139 of the window 135. The substrate support 191 is disposed in the interior volume 102. The processing chamber 110 includes a gas inlet 197 formed in the first portion 184 (e.g., the sidewall) of the chamber body 185. The present disclosure contemplates that the gas inlet 197 can be formed through the ceiling 103, such as through the window 135. The gas inlet 197 is fluidly coupled to a first inlet path 107 and a first gas source 109 to introduce the one or more process gases 111 into the interior volume 102. During the processing operation, the first gas source 109 is used to introduce the one or more process gases 111 into the interior volume 102 through one or more valves (a supply valve 123 is shown in FIG. 1) disposed along the first inlet path 107.

A motor 124 can be coupled to the window 135 and/or the filter 139 to move at least a portion of the window 135 and/or the filter 139 upwardly and downwardly. Movement of at least the portion of the window 135 and/or filter 139 upwardly and downwardly moves the ceiling 103 upwardly and downwardly to optionally oscillate a distance D1 between the ceiling 103 of the interior volume 102 and the upper surface 133 of the substrate 192. Oscillating the ceiling 103 upwardly and downwardly oscillates a volume of the processing region 118. The present disclosure contemplates that a different upper component, such as a showerhead or a gas distribution plate, may be used in place of the window 135 and the filter 139.

In one embodiment, which can be combined with other embodiments, a diaphragm 181 may be positioned below the window 135 and above the substrate 192 such that the diaphragm 181 defines the ceiling 103 of the interior volume 102. The diaphragm 181 has a low mass and/or a compressible material such that the diaphragm 181 is movable, such as by the motor 124 and/or by the processing gases 111, 131. The diaphragm 181 is oscillated upwardly and downwardly to oscillate the distance D1 between the ceiling 103 of the interior volume 102 and the upper surface 133 of the substrate 192.

The processing chamber 110 includes a gas outlet 161 (such as an exhaust port) fluidly coupled to an outlet path 112 and a vacuum pump 1001 to exhaust the one or more process gases 111 from the interior volume 102. The gas outlet 161 is formed vertically in the second portion 186 of the chamber body 185. A rotatable valve 182 is disposed upstream of the vacuum pump 1001 along the outlet path 112. The rotatable valve 182 includes a valve housing 114 and a flapper 115 that is freely rotatable relative to the valve housing 114. The gas outlet 161 is formed on an opposite side of the substrate support 191 and the substrate 192 relative to the gas inlet 197. The gas outlet 161 is formed radially outside of the substrate support 191 and the substrate 192. A pump motor 117 is coupled to the rotatable valve 182 to rotate the flapper 115. A pressure control valve (PCV) 169 is disposed between the rotatable valve 182 and the vacuum pump 1001 along the outlet path 112. The PCV 169 is utilized to control and maintain the pressure within the interior volume 102 of the processing chamber 110. The PCV 169 is selectively opened, closed, or partially opened (e.g., throttled) to change the rate at which the processing gases 111 are exhausted from the processing chamber 110.

A second vacuum pump 119 can optionally be connected to the lamp assembly 183. The pressure within the lamp assembly 183 is controlled by a valve 121 disposed in a foreline of the second vacuum pump 119. During the processing operation, the pump motor 117 rotates the flapper 115 in a rotational direction while the one or more process gases 111 are introduced into the interior volume 102, thereby oscillating a pressure of the interior volume 102. In one embodiment, which can be combined with other embodiments, the flapper 115 rotates in a single continuous rotational direction.

The present disclosure contemplates that the gas outlet 161 can be formed horizontally in the first portion 184 on an opposite side of the substrate support 191 and the substrate 192 relative to the gas inlet 197. As the one or more processing gases 111 flow from the gas inlet 197 and toward the gas outlet 161, the one or more processing gases 111 move over the upper surface 133 of the substrate 192.

In one embodiment, which can be combined with other embodiments, the one or more process gases 111 and/or the one or more process gases 131 include one or more of Ar, O₂, He, and/or H₂O.

An annular channel 187 is formed in the chamber body 185, and a rotor 196 is disposed in the channel 187. The channel 187 is located adjacent to the second portion 186 of the chamber body 185. The processing chamber 110 further includes a rotatable support member 189 disposed in the channel 187. The rotatable support member 189 is supported on and/or coupled to the rotor 196. The substrate support 191 is supported on the rotatable support member 189, and a shield 194 is disposed on the second portion 186 of the chamber body 185. The rotatable support member 189 is fabricated from a material having minimal change in material properties, such as tensile strength or thermal expansion, across a range of temperatures, or resistance to degradation due to exposure to heat. An exemplary material for the rotatable support member 189 is quartz. In one embodiment, which can be combined with other embodiments, the rotatable support member 189 is cylindrical, such as a cylindrical sleeve. In one embodiment, which can be combined with other embodiments, the substrate support 191 is an annular edge ring on which an outer periphery, such as an outer circumferential edge, of the substrate 192 is supported during the processing operation conducted on the substrate 192. The rotatable support member 189 and the substrate support 191 are at least a part of a substrate support assembly.

The channel 187 has an outer wall 150 and an inner wall 152. A lower first portion 154 of the outer wall 150 has a first radius and an upper second portion 156 of the outer wall 150 has a second radius greater than the first radius. A third portion 158 of the outer wall 150 connecting the first portion 154 to the second portion 156 has a cross-sectional profile that extends linearly from the first portion 154 to the second portion 156, forming a slanted surface that faces toward the substrate support 191. The shield 194 has a first portion 160 that rests on the second portion 186 of the chamber body 185 and a second portion 162 that extends into the channel 187 along the second portion 156 of the outer wall 150. The first portion 160 of the shield 194 contacts the second portion 186 of the chamber body 185, and the second portion 162 of the shield 194 contacts the second portion 156 of the outer wall 150. The shield 194 extends partially over the channel 187. In one embodiment, which can be combined with other embodiments, the shield 194 is a rotor cover. The shield 194 is an annular ring. The shield 194 may have one or more gaps extending in a radial direction from a center thereof. The shield 194 can be fabricated from a ceramic material, such as alumina. The shield 194 further includes a first surface 193 facing the window 135. The first surface 193 is substantially flat, and is oriented away from a portion of a processing region 118 of the processing chamber 110 located above the substrate 192, so radiant energy is not reflected therefrom towards the substrate 192. In one embodiment, which can be combined with other embodiments, the first surface 193 of the shield 194 is substantially parallel to the window 135. In one embodiment, which can be combined with other embodiments, the first surface 193 is annular. The processing region 118 of the interior volume 102 is between the substrate 192 and the ceiling 103.

The substrate 192 is disposed on the substrate support 191 during the processing operation. A stator 195 is located external to the chamber body 185 in a position axially aligned with the rotor 196. The rotor 196 is disposed in the interior volume 102 and inwardly of the stator 195. The substrate support 191 is supported on the rotor 196 through the rotatable support member 189, and the substrate support 191 is movable upwardly and downwardly using the rotor 196 and the stator 195.

In one embodiment, which can be combined with other embodiments, the stator 195 is a magnetic stator, and the rotor 196 is a magnetic rotor. The stator 195 has a plurality of electric coils therein which circumscribe the channel 187. During operation, the stator 195 applies a sequence of currents to the coils at defined intervals. The currents within the coils create a series of magnetic fields which are coupled to a magnetic portion of the rotor 196, such as a magnet disposed therein, through the outer wall 150. The currents are applied to the coils in a sequence so that the magnetic fields formed therein attract the magnetic portion of the rotor 196 and bias the rotor 196 to rotate about an axis which in turn rotates the rotatable support member 189 magnetically coupled thereto, the substrate support 191, and the substrate 192. The currents applied to the coils of the stator 195 can also be used to move the rotor 196 upwardly and downwardly within the interior volume. During the processing operation, the currents are pulsed to oscillate the rotor 196, and hence oscillate the substrate support 191 and the substrate 192, upwardly and downwardly within the interior volume 102. The currents are pulsed to oscillate a height H1 of the substrate support 191 in the interior volume 102. In one embodiment, which can be combined with other embodiments, the height H1 is between the substrate support 191 and the chamber base 188. In one embodiment, which can be combined with other embodiments, the height H1 is between the substrate support 191 and the second portion 186. Oscillating the height H1 oscillates a height of the substrate 192 disposed on the substrate support 191.

During the processing operation, a temperature of the substrate support 191 may raise more than a temperature of the substrate 192, thereby raising a temperature of an edge of the substrate 192 relative to a center of the substrate 192. A cooling member 151 can be disposed on the chamber base 188 in proximity to the substrate support 191 to cool the substrate support 191 using convection. The cooling member 151 convects heat from the substrate support 191 and the substrate 192 when disposed thereon. The chamber base 188 includes a first surface 120 and a second surface 122 opposite the first surface 120. As shown in FIG. 1, the cooling member 151 is in direct contact with the first surface 120 of the chamber base 188.

A thickness of the substrate support 191 may be selected to provide a desired thermal mass. The substrate support 191 can act as a heat sink, which mitigates overheating at the edge of the substrate 192. In one embodiment, which can be combined with other embodiments, a feature 144, such as a fin, is formed on the substrate support 191 to provide thermal mass. The feature 144 may be continuous, for example cylindrical, or discontinuous, for example a plurality of discrete fins.

The feature 144 may be formed on a surface of the substrate support 191 that is facing the channel 187 when the substrate support 191 is installed in the chamber 100, and may extend into the channel 187, as shown in FIG. 1A. In one embodiment, which can be combined with other embodiments, the feature 144 is formed on a surface of the substrate support 191 that is facing the window 135. In one embodiment, which can be combined with other embodiments, a combination of one or more features 144 facing the channel 187 and one or more features 144 facing the window 135 may be used. As depicted in FIG. 1A, the feature 144 may be substantially perpendicular to a major surface of the substrate support 191. In one embodiment, which can be combined with other embodiments, the feature 144 may extend obliquely from the major surface of the substrate support 191.

The chamber base 188 includes a plurality of channels 157 formed therein for a coolant, such as water, to flow therethrough. Cooling the chamber base 188 also draws heat from, and thus cools, the cooling member 151. The cooling member 151 may be fabricated from a material having high heat conductivity, such as a metal, for example, aluminum. The cooling member 151, in turn, functions as a heat sink to the substrate support 191 due to close proximity of the cooling member 151 to the substrate support 191.

The cooling member 151 includes a recess 104 formed in the surface thereof that is in contact with the first surface 120 of the chamber base 188. The recess 104 can be used to circulate a cooling fluid for further cooling of the cooling member 151. In one embodiment, which can be combined with other embodiments, the cooling member 151 is an annular ring, and the recess 104 is an annular recess. A cooling gas may be flowed from a gas source 106 through the cooling member 151 via the recess 104 to provide additional cooling of the cooling member 151. The cooling gas increases heat transfer between the cooling member 151 and the substrate support 191, thus further cooling the substrate support 191. The cooling gas may be helium, nitrogen, or other suitable gas. The cooling gas flows through a passage 108 formed in the chamber base 188 and through a channel 105 defined between the recess 104 and the first surface 120 of the chamber base 188.

The controller 1002 is configured to control various operations of the system 101 described above. The controller 1002 is also configured to control various operations described herein. The controller 1002 is coupled to at least one or more of the lamps 155, the vacuum pump 1001, the PCV 169, the rotatable valve 182, the pump motor 117, the stator 195, the first gas source 109, the supply valve 123, and/or the motor 124. The controller 1002 is configured to cause one or more of the operations of the method 300 described below to be conducted. The controller 1002 includes a non-transitory computer-readable medium. The controller 1002 includes a processor, support circuitry, and instructions that—when executed by the processor—cause the operations to be conducted.

The instructions of the controller 1002 can include one or more machine learning/artificial intelligence algorithms that can be executed in addition to the operations described herein. As an example, a machine learning/artificial intelligence algorithm executed by the controller 1002 can optimize and alter a pulse frequency (e.g., an oscillation frequency) of the supply of process gases based on a residence time frequency of reactants within the interior volume 102.

The pulse frequency is the inverse of the residence time frequency. The machine learning/artificial intelligence algorithm can account for a measured residence time frequency, a known volume amount of the interior volume 102, and composition(s) of the process gases 111, 131.

FIG. 1B is an enlarged partial schematic view of the system 101 shown in FIG. 1A during the processing operation, according to one implementation. FIG. 1B illustrates a flow 140 of the one or more process gases 111 and/or the one or more process gases 131 between the substrate 192 and the window 135. The flow 140 has a flow profile with a peak velocity 141. In one embodiment, which can be combined with other embodiments, the peak velocity 141 is about 50 meters per second. The flow 140 has a boundary layer 142. The boundary layer 142 has a thickness T1. The boundary layer 142 having the thickness T1 is a portion of the flow 140 that is on the side of the peak velocity 141 adjacent the upper surface 133 of the substrate 192 where a velocity is within a range of 5% to 10% of the peak velocity 141.

FIG. 1C is a schematic graphical illustration of an oscillation frequency 145, according to one implementation. As shown in FIG. 1C, the oscillation frequency has a sinusoidal profile, which can be used for the various parameters described herein that are oscillated. The “P” of the vertical axis represents units of an operational parameter described herein, such as the pressure in the interior volume 102, an amount of the one or more processing gases 111 and/or the one or more processing gases 131 in the interior volume 102, the height H1, the distance D1, and/or the distance D2. In one embodiment, which can be combined with other embodiments, oscillating such parameters oscillates the thickness T1 of the boundary layer 142 and/or a distance of the boundary layer 142 relative to the substrate 192. In one embodiment, which can be combined with other embodiments, oscillating such parameters oscillates the thickness T1 of the boundary layer 142. The “T” of the horizontal axis” represents time.

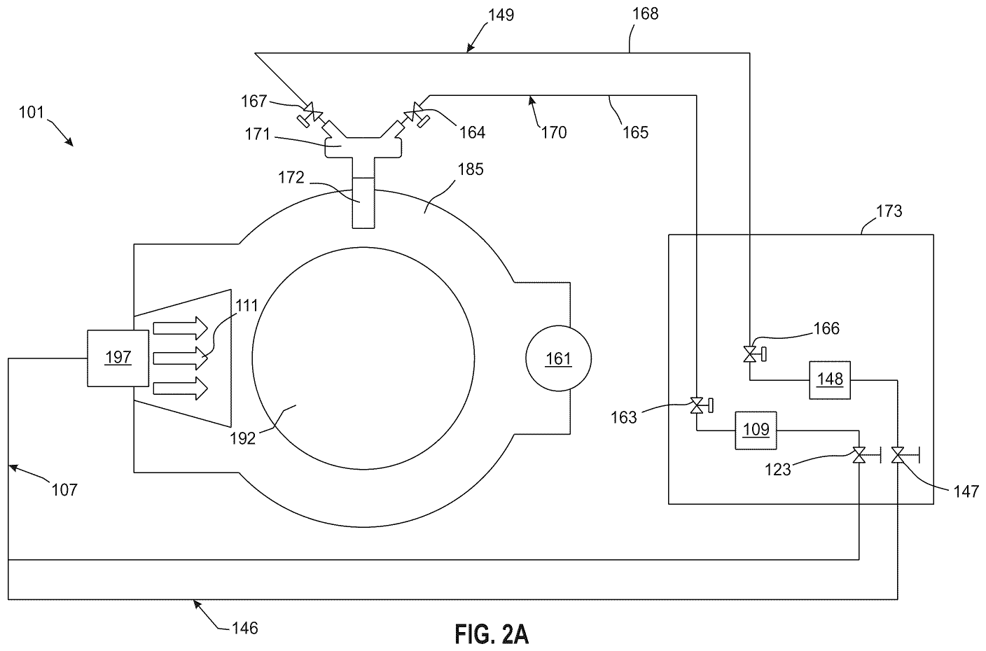

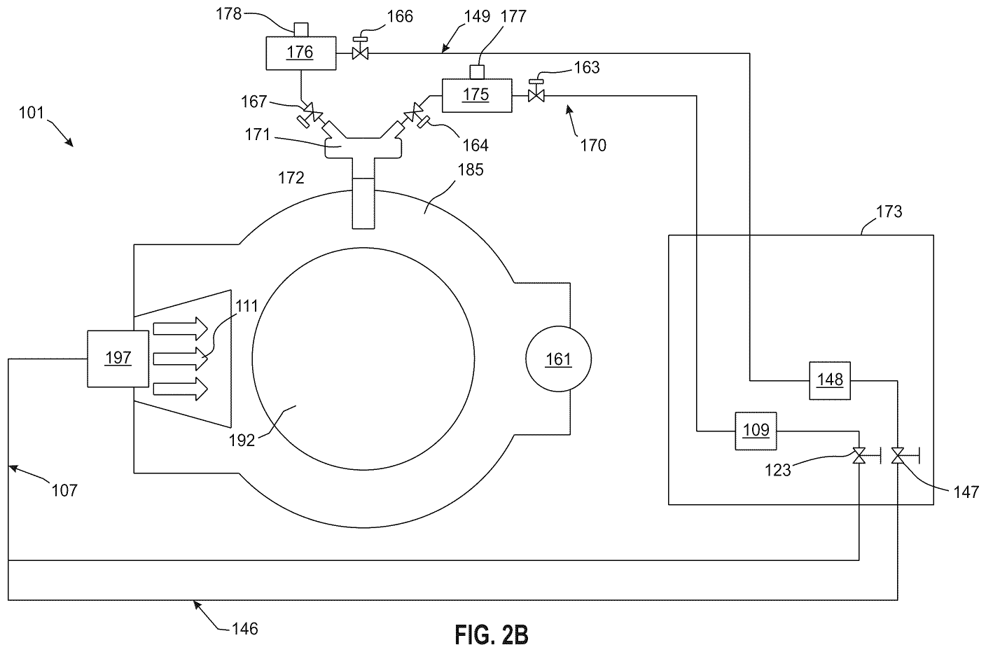

FIG. 2A is a schematic partial top view of the system 101 shown in FIG. 1A, according to one implementation. A second inlet path 146 having a supply valve 147 joins with the first inlet path 107 leading to the gas inlet 197. The supply valve 147 disposed along the second inlet path 146 is fluid coupled to a second gas source 148. To oscillate an amount of the one or more processing gases 131 in the interior volume 102, a first supply valve 163 coupled to the first gas source 109 along the first supply path 170 is opened while a second supply valve 164 is closed. The second supply valve 164 is downstream from the first supply valve 163 along the first supply path 170. Opening the first supply valve 163 while the second supply valve 164 is closed charges a charge volume of a line 165 between the first supply valve 163 and the second supply valve 164. After the opening of the first supply valve 163, the first supply valve 163 is closed and the second supply valve 164 is opened while the first supply valve 163 is closed to introduce the one or more process gases from the first gas source 109 into the interior volume 102. Opening the second supply valve 164 runs and releases the process gases from the charge volume of the line 165 into the interior volume 102. The opening the first supply valve 163 while the second supply valve 164 is closed, the closing of the first supply valve 163, and the opening the second supply valve 164 while the first supply valve 163 is closed can be repeated to pulse the supply of the process gases from the first gas source 109.

The second supply path 149 includes a first supply valve 166 and a second supply valve 167 disposed along the second supply path 149. The first supply valve 166 and the second supply valve 167 can be operated in a manner similar to the first supply valve 163 and the second supply valve 164 of the first supply path 170 to pulse the supply of the one or more process gases from the second gas source 148. A charge volume of a line 168 between the first supply valve 166 and the second supply valve 167 is used to pulse the supply of the one or more process gases from the second gas source 148. The process gases from the first supply path 170 and the process gases from the second supply path 149 join at a gas block 171. The gas block 171 and/or the gas conduit 172 extend at least partially through a sidewall (such as the first portion 184) of the chamber body 185.

In the implementation shown in FIG. 2A, the first gas source 109, the second gas source 148, the supply valve 123, the supply valve 147, the first supply valve 163, and the first supply valve 166 are disposed within a gas box 173. The present disclosure contemplates that respective orifices of the valves 163, 164, 166, and 167 may be varied (e.g., altered) without completely closing or completely opening the orifices to pulse the supply of the one or more process gases 131 and oscillate an amount of the one or more process gases 131 in the interior volume 102. The respective orifices may be oscillated. The present disclosure contemplates that the respective valves 163, 164, 166, and 167 may be completely closed and completely opened to pulse the supply of the one or more process gases 131 and oscillate an amount of the one or more process gases 131 in the interior volume 102. In one embodiment, which can be combined with other embodiments, the supply of the one or more process gases 111 is provided at a substantially constant gas flow while the boundary layer is oscillated as described herein. In one embodiment which can be combined with other embodiments, each of the first supply valve 163 and the first supply valve 166 is a fast valve having a cycle rate (a rate at which the valve can open and close) that is 0.02 seconds-per-gas or less. In one embodiment, which can be combined with other embodiments, the cycle rate is 0.01 seconds-per-gas. In one example, which can be combined with other examples, each fast valve pulses two gases at the cycle rate of 0.01 seconds-per-gas or less such that a single pulse cycle of the two gases lasts 0.02 seconds or less. In one embodiment, which can be combined with other embodiments, each of the first supply valve 163 and the first supply valve 166 is a fast valve having a switching rate (a rate at which the valve switches between open and close) that is 0.01 seconds or less.

Each of the second gas source 148, the supply valve 147, the first supply valve 163, the second supply valve 164, the first supply valve 166, and/or the second supply valve 167 can be coupled to the controller 1002 (shown in FIG. 1A) to control the operations thereof.

FIG. 2B is a schematic partial top view of the system 101 shown in FIG. 1A, according to one implementation. The implementation shown in FIG. 2B is similar to the implementation shown in FIG. 2A. In the implementation shown in FIG. 2B, the first supply valve 163 and the first supply valve 166 are disposed outside of the gas box 173 and further downstream along the respective first supply path 170 and second supply path 149. In the implementation shown in FIG. 2B, a first charge volume 175 is positioned between the first supply valve 163 and the second supply valve 164 along the first supply path 170, and a second charge volume 176 is positioned between the first supply valve 166 and the second supply valve 167 along the second supply path 149. Each of the first charge volume 175 and the second charge volume 176 is part of a respective container having a pressure gauge 177, 178 coupled thereto. Each of the first charge volume 175 and the second charge volume 176 has an internal width (such as an internal diameter) that is larger than an internal width (such as internal diameter) of the respective first or second supply path 170, 149. The first charge volume 175 and the second charge volume 176 can be charged and ran (e.g., released), as described for the charge volumes of the lines 165, 168 of the implementation shown in FIG. 2A.

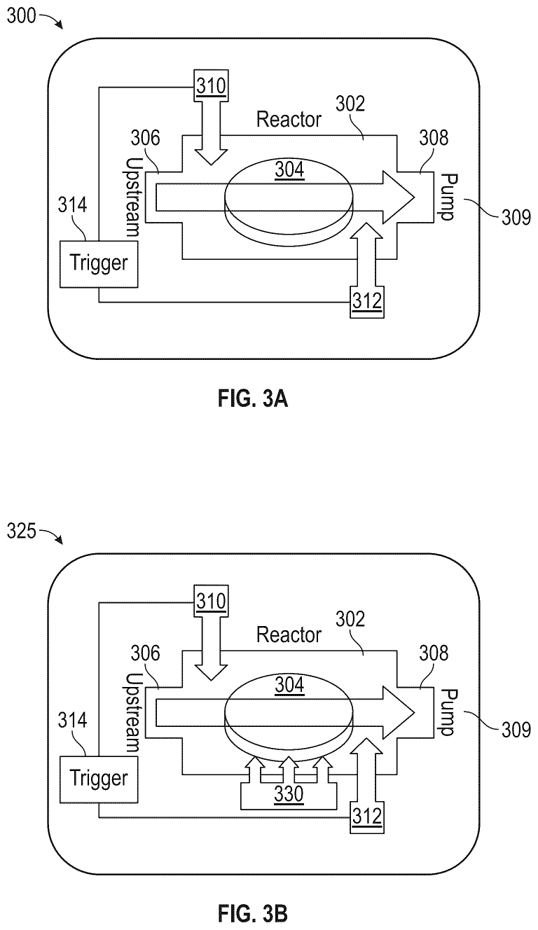

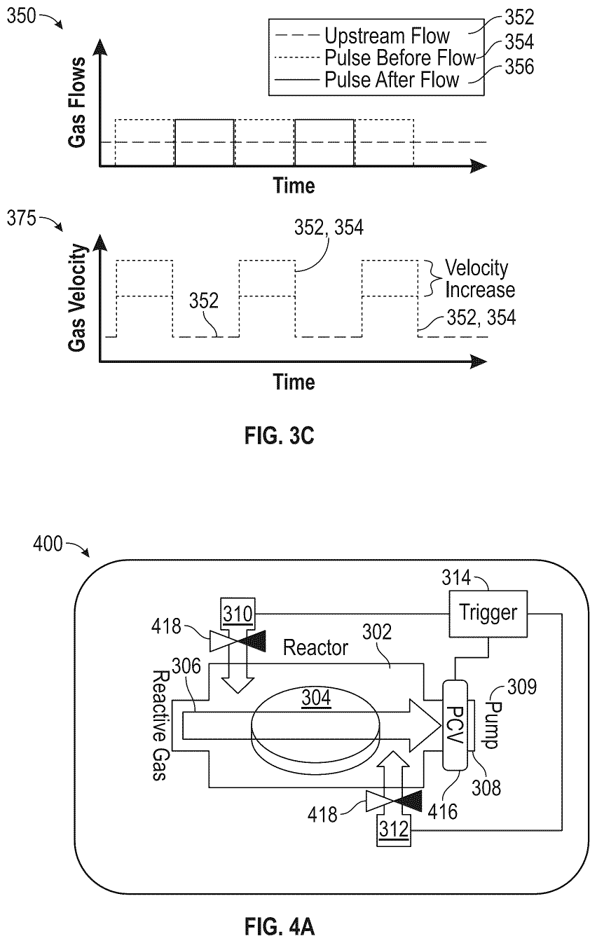

FIG. 3A schematically illustrates a portion of a processing chamber 300, according to one embodiment. FIG. 3B schematically illustrates a portion of a processing chamber 325, according to another embodiment. The processing chambers 300, 325 may each individually be within or utilized with the system 101 of FIGS. 1A-2B.

The processing system 300 comprises an inner chamber or reactor 302 where a substrate 304 is to be processed. The inner chamber 302 comprises a gas inlet 306 where processing gas is injected into the inner chamber 302, and an outlet or exhaust 308 coupled to a pump 309 where the processing gas is pumped out of the inner chamber 302. A substrate 304 disposed on a substrate holder (covered by the substrate) is disposed between the gas inlet 306 and the exhaust 308. A first inert gas injector 310 is disposed between the substrate 304 and the inlet 306, and a second inert gas injector 312 is disposed between the substrate 304 and the exhaust 308.

The first and second injectors 310, 312 are configured pulse inert or process gas into the inner chamber 302 when processing a substrate 304. In one embodiment, the first injector 310 pulses inert gas prior to the processing gas flowing into the inner chamber 302, and the second injector 312 pulses inert gas as processing gas is flowing into the inner chamber 302. In another embodiment, the first and second injectors 310, 312 each pulse inert or process gas into the inner chamber 302 as the process gas is flowing into the inner chamber 302.

The pulses of the first and second injectors 310, 312 are synchronized such that the first and second injectors 310, 312 are not pulsing at the same time. For example, the first injector 310 first pulses inert gas into the inner chamber 302, and the second injector 312 then pulses inert gas into the inner chamber 302 immediately after (i.e., about 0.01 seconds to about 1 second) the first pulse is completed, or vice versa, as discussed below in FIG. 3B. A trigger or controller 314 is coupled to the first and second injectors 310, 312, and may be used to control the timing of the inert gas pulses. Each gas pulse from the first and second injectors 310, 312 lasts a period of time of about 0.01 seconds to about 2 seconds at a gas pulse flow of about 1 slm to about 20 slm. The synchronized gas pulses of the first and second injectors 310, 312 modulates the velocity such that the magnitude of the velocity at the substrate 304 is increased, thus decreasing dampening effects from the pressure of the chamber 300. As a result, the chemical reaction rate and deposition rate is still high, and the processing of the substrate 304 is more uniform.

The processing gas may comprise O₂ or H₂, but this implementation may be applied to chemical vapor deposition (CVD) as well. The inert gas may comprise Ar, N₂, or He. The processing gas flows at a constant rate of about 1 slm to about 200 slm during processing of the substrate 304. During processing, the chamber 300 is pressurized to about 1 torr to about 300 torr at a frequency of about 1 Hz to about 100 Hz.

FIG. 3B schematically illustrates a portion of a processing chamber 325, according to another embodiment. The processing chamber 325 is the same as the processing chamber 300 of FIG. 3A; however, the inner chamber 302 comprises multi-injects 330 disposed adjacent to the substrate 304. The multi-injects 330 are configured to inject additional processing gas over the substrate 304. In one example, the multi-injects 330 inject processing gas concurrently with injection from the inlet 306, in a non-pulsed (e.g., continuous flow) manner.

FIG. 3C illustrates a first graph 350 showing gas flows versus time during processing a substrate 304 in the processing chamber 300 of FIG. 3A, and a second graph 375 showing gas velocity versus time during processing a substrate 304 in the processing chamber 300 of FIG. 3A, according to embodiments. In each graph 350, 375, line 352 represents the processing gas, line 354 represents the inert gas pulse of the first injector 310, and line 356 represents the inert gas pulse of the second injector 312.

The graph 350 shows that the processing gas represented by line 352 flows at a constant rate during processing of the substrate 304. The graph 350 further illustrates the timing of the pulses of the first and second injectors 310, 312 such that once the first injector 310 finishes pulsing gas (line 354), the second injector 312 immediately pulses gas (line 356). The graph 375 shows that by utilizing the synchronized pulses of the first and second injectors 310, 312, the velocity of the gas is significantly increased.

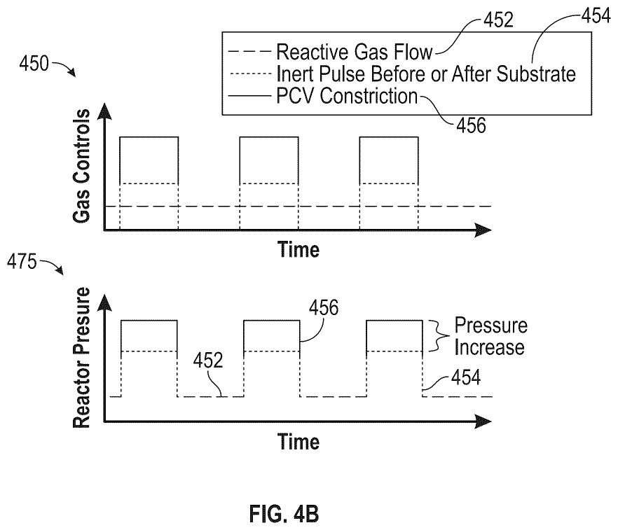

FIG. 4A schematically illustrates a portion of a processing chamber 400, according to another embodiment. The processing chamber 400 may be within or utilized with the system 101 of FIGS. 1A-2B. Aspects of the processing chamber 400 may be used in combination with aspects of the processing chamber 300 of FIG. 3A. For example, the chamber 400 may comprise the multi-injects 330 of FIG. 3B.

The processing chamber 400 is similar to the processing chamber 300 of FIG. 3A; however, the processing chamber 400 comprises a pressure control valve (PCV) 416 disposed on the exhaust 308. Additionally, the first and second injectors 310, 312 are optional in that the processing chamber 400 may comprise either the first or second injector 310, 312 or both the first and second injectors 310, 312. In one embodiment, the processing chamber 400 does not comprise the first and second injectors 310, 312. The controller 314 is also optional, and the processing chamber 400 may include the first and/or second injectors 310, 312 with or without the controller 314. In such an embodiment where the processing chamber 400 does not comprise the controller 314 but does comprise either the first or second injector 310, 312, a valve 418 may be used pulse gas through the first or second injector 310, 312.

The PCV 416 is configured to constrict (or permit) the flow of the processing gas through the exhaust 308. The PCV 416 may fully or partially restrict the exhaust 308 such that the PCV 416 may be fully opened, fully closed, or partially opened. Constricting the exhaust 308 by closing or partially closing the PCV 416 modulates and increases the pressure within the inner chamber 302 when the substrate is being processed, which improves the chemical processing of the substrate 304. When utilizing the PCV 416 in combination with an inert gas pulse before the substrate 304 via the first injector 310 or an inert gas pulse after the substrate 304 via the second injector 312, the pressure within the inner chamber 302 is further increased, as discussed below in FIG. 4B. Pulsing the inert gas before the substrate 304 via the first injector 310 increases the velocity within the inner chamber 302, and after the substrate 304 via the second injector 312 further increases the pressure within the inner chamber 302.

FIG. 4B illustrates a first graph 450 showing gas flows versus time during processing a substrate 304 in the processing chamber 400 of FIG. 4A, and a second graph 475 showing pressure of the inner chamber 302 versus time during processing a substrate 304 in the processing chamber 400 of FIG. 4A, according to embodiments. In each graph 450, 475, line 452 represents the processing gas, line 454 represents an inert gas pulse of the first or second injector 310, 312, and line 456 represents constricting the exhaust 308 using the PCV 416.

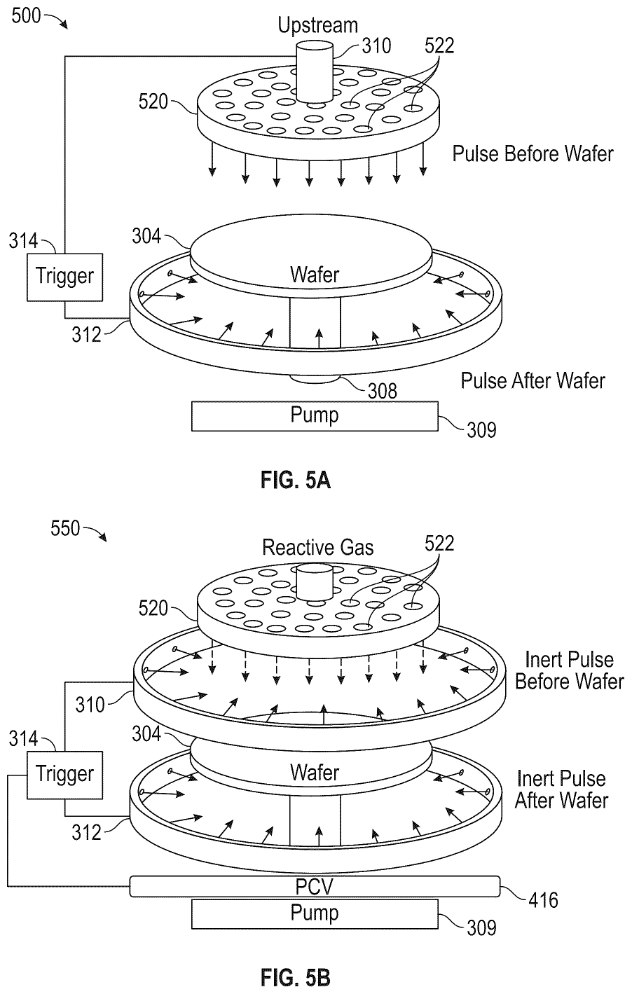

FIG. 5A illustrates a showerhead configuration 500 of the chamber 300 of FIG. 3A, according to one embodiment. In the showerhead configuration 500, a showerhead 520 is disposed above the substrate 304. The showerhead 520 may be the gas inlet 306 of FIGS. 3A-3B. The showerhead 520 is configured to inject processing gas onto the substrate 304 and to pulse inert or process gas as the first injector 310. For example, one or more apertures 522 of the showerhead 520 may be coupled to a first zone (not shown) where processing gas is located, and one or more other apertures 522 may be coupled to a second zone (not shown) where inert gas is located. The second injector 312 is disposed between the substrate 304 and the pump 309 in a ring formation. The second injector 312 is configured to inject a gas, such as an inert gas, radially inward from the ring to promote processing uniformity while modulating pressure within the chamber.

FIG. 5B illustrates a showerhead configuration 550 of the chamber 400 of FIG. 4A, according to one embodiment. In the showerhead configuration 550, the showerhead 520 is configured to inject processing gas onto the substrate 304. The first injector 310 is disposed between the showerhead 520 and the substrate 304 in a ring formation. The second injector 312 is disposed between the substrate 304 and the PCV 416 in a ring formation. It is contemplated that one or more of the PCV 416, the first injector 310, or the second injector 312 may be omitted.

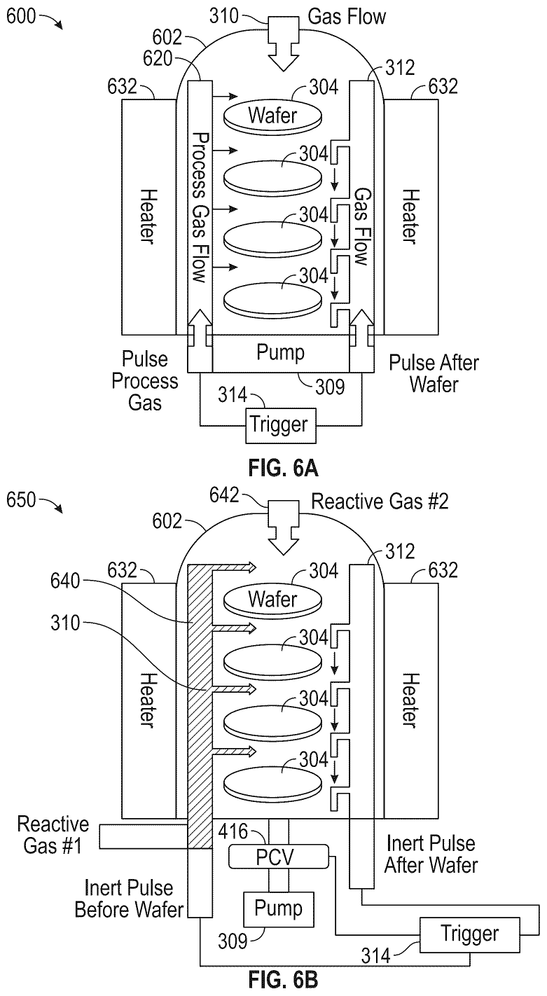

FIG. 6A illustrates a cross-sectional view of a furnace configuration 600 of the chamber 300 of FIG. 3A, according to another embodiment. The furnace 600 comprises an interior chamber 602 where one or more substrates 304 will be processed. One or more heaters 632 are disposed around an exterior of the furnace 600. Processing gas flows up through a first gas delivery mechanism 640 where it then flows over the surface of each substrate 304. The first injector 310 is disposed at a top of the inner chamber 602 to pulse inert or process gas prior to the processing gas flowing over the substrates 304. The second injector 312 is disposed opposite the first gas delivery mechanism to pulse inert or process gas after the processing gas flows over the substrates. The second injector 312 may comprise a second gas delivery system similar to the first gas delivery mechanism 640.

FIG. 6B illustrates a cross-sectional view of a furnace (or vertical batch) configuration 650 of the chamber 400 of FIG. 4A, according to another embodiment. The furnace 650 of FIG. 6B is similar to the furnace 600 of FIG. 6A; however, the first gas delivery mechanism 640 further comprises the first injector 310. The furnace 650 further comprises the PCV 416 and a third gas delivery mechanism 642 disposed at the top of the inner chamber 602. The first gas delivery mechanism 640 is configured to pulse inert or process gas prior to then flowing the processing gas over the surface of the substrates 304. The first gas delivery mechanism 640 is configured to individually pulse the insert gas and flow the processing gas such that the first gas delivery mechanism 640 releases only one gas at a time, either the inert gas or the processing gas.

Therefore, by releasing synchronized gas pulses of inert gas in a processing chamber using a first and second injector, one pulse before the substrate and a second pulse after the substrate, the velocity is modulated such that the magnitude of the velocity at the substrate is increased, thus decreasing dampening effects from the pressure of the processing chamber. As a result, the chemical reaction rate and deposition rate is still high, and the processing of the substrate is more uniform.

By constricting the exhaust of processing gas within a chamber by closing or partially closing a PCV, the pressure within the inner chamber is modulated and increased at the substrate is being processed, which improves the chemical processing of the substrate. Pulsing the velocity at a distance from the substrate results in the magnitude of the velocity being much smaller by the time it reaches the substrate due to dampening effects from chamber pressure. However, having two synchronized pulses, one before and one after the substrate, allows the magnitude of the velocity over the substrate to be amplified. When utilizing the PCV in combination with an inert gas pulse before the substrate via the first injector or an inert gas pulse after the substrate via the second injector, the pressure within the inner chamber is further increased.

While the foregoing is directed to embodiments of the present disclosure, other and further embodiments of the disclosure may be devised without departing from the basic scope thereof, and the scope thereof is determined by the claims that follow.

What is claimed is:

1. A processing chamber, comprising:
an inner chamber;
a gas inlet disposed on a first end of the inner chamber, the gas inlet being configured to flow processing gas into the inner chamber;
an exhaust disposed on a second end of the chamber opposite the first end, the exhaust being coupled to a pump configured to remove processing gas from the inner chamber;
a substrate holder disposed between the gas inlet and the exhaust, the substrate holder being configured to hold one or more substrates;
a first gas injector for injecting gas between the gas inlet and the substrate holder, the first gas injector being configured to pulse an inert gas or a processing gas into the inner chamber a first time;
a second gas injector for injecting gas between the substrate holder and the exhaust, the second gas injector being configured to pulse the inert or processing gas into the inner chamber a second time; and
a controller coupled to the first and second gas injectors, the controller being configured to control the first and second gas injectors such that the timing of the pulses of the inert or processing gas the first and second times are synchronized.

2. The processing chamber of claim 1, wherein the gas inlet is a showerhead.

3. The processing chamber of claim 2, wherein the first gas injector is disposed within the showerhead.

4. The processing chamber of claim 1, wherein the processing chamber is a vertical batch chamber.

5. The processing chamber of claim 4, further comprising furnace PCV valves for controlling gas flow through the exhaust, the PCV valve synchronized with the first and second gas injectors.

6. The processing chamber of claim 1, wherein the controller is configured to:
pulse the inert or processing gas the first time period after the processing gas is flowing into the inner chamber; and
pulse the inert or processing gas the second time period after the processing gas is flowing into the inner chamber, the second time period different than the first time period.

7. The processing chamber of claim 1, further comprising multi-injects configured to inject additional processing gas into the inner chamber at a location between the first and second gas injectors.

8. A processing chamber, comprising:
an inner chamber;
a gas inlet disposed on a first end of the inner chamber, the gas inlet being configured to flow processing gas into the inner chamber;
an exhaust disposed on a second end of the inner chamber opposite the first end, the exhaust being coupled to a pump configured to remove processing gas from the inner chamber;
a substrate holder disposed between the gas inlet and the exhaust, the substrate holder being configured to hold one or more substrates;
a pressure control valve (PCV) coupled to the exhaust, the PCV configured to close or partially close during processing of a substrate to constrict the exhaust; and
a gas injector configured to pulse inert or process gas into the inner chamber.

9. The processing chamber of claim 8, wherein the gas injector injects gas to a location between the gas inlet and the substrate holder.

10. The processing chamber of claim 8, wherein the gas injector is configured to inject or processing gas between the substrate holder and the PCV.

11. The processing chamber of claim 8, further comprising a controller configured to synchronize the gas injector and the PCV valve to modulate pressure within the inner chamber.

12. The processing chamber of claim 8, wherein the gas inlet is a showerhead.

13. The processing chamber of claim 8, further comprising multi-injects configured to inject additional processing gas into the inner chamber.

14. A processing system, comprising:
a processing chamber, the processing chamber comprising:
an inner chamber;
a gas inlet disposed on a first end of the inner chamber, the gas inlet being configured to flow processing gas into the inner chamber;
an exhaust disposed on a second end of the inner chamber opposite the first end, the exhaust being coupled to a pump configured to remove processing gas from the inner chamber;
a substrate holder disposed between the gas inlet and the exhaust, the substrate holder being configured to hold one or more substrates;
a first gas injector disposed between the gas inlet and the substrate holder, the first gas injector being configured to pulse an inert or processing gas into the inner chamber a first time;
a second gas injector disposed between the substrate holder and the exhaust, the second gas injector being configured to pulse the inert or processing gas into the inner chamber a second time; and
a controller coupled to the first and second gas injectors, the controller being configured to control the first and second gas injectors such that the timing of the pulses of the inert or processing gas the first and second times are synchronized.

15. The processing system of claim 14, wherein the gas inlet is a showerhead.

16. The processing system of claim 15, wherein the first gas injector is disposed within the showerhead.

17. The processing system of claim 14, wherein the processing chamber is a vertical batch chamber.

18. The processing system of claim 17, further comprising furnace PCV valves for controlling gas flow through the exhaust, the PCV valve synchronized with the first and second gas injectors.

19. The processing system of claim 14, wherein the controller is configured to:
pulse the inert or processing gas the first time after the processing gas is flowing into the inner chamber; and
pulse the inert or processing gas the second time after the processing gas is flowing into the inner chamber.

20. The processing system of claim 14, further comprising multi-injects configured to inject additional processing gas into the inner chamber.
